(19) United States
(12) Patent Application Publication
(10) Pub. No.: US 2006/0220034 A1
(43) Pub. Date: Oct. 5, 2006

(54) Thin film transistor with capping layer and method of manufacturing the same

(75) Inventors: Huaxiang Yin, Gyeonggi-do (KR); Takashi Noguchi, Gyeonggi-do (KR); Wenxu Xianyu, Gyeonggi-do (KR); Do-young Kim, Gyeonggi-do (KR); Ji-sim Jung, Incheon-si (KR); Jang-yeon Kwon, Gyeonggi-do (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/369,947

(22) Filed: Mar. 8, 2006

(30) Foreign Application Priority Data
Mar. 15, 2005 (KR) 10-2005-0021377

(51) Int. Cl. H01L 33/00

(52) U.S. Cl. 257/79

(57) ABSTRACT

A thin film transistor and a method of manufacturing the thin film transistor. The thin film transistor may include a substrate, a buffer layer, a polysilicon layer, a gate insulating layer and/or a gate electrode, and a capping layer. The buffer layer may be formed on the substrate. The polysilicon layer may be formed on the buffer layer, and may include a first doped region, a second doped region, and a channel region. The gate insulating layer and a gate electrode may be sequentially stacked on the channel region of the polysilicon layer. The capping layer may be stacked on the gate electrode.

### PRIORITY STATEMENT

This application claims the benefit of Korean Patent Application No. 10-2005-0021377, filed on Mar. 15, 2005, in the Korean Intellectual Property Office, the disclosure of which is incorporated herein in its entirety by reference.

### BACKGROUND OF THE INVENTION

1. Field of the Invention

Example embodiments of the present invention relate to a semiconductor device and a method of manufacturing the same, and more particularly, to a thin film transistor with a capping layer and a method of manufacturing the same.

2. Description of the Related Art

Thin film transistors (TFTs) are widely used in flat panel displays such as liquid crystal displays (LCDs). TFTs may be classified into top gate TFTs with a gate overlying a channel and bottom gate TFTs with a gate underlying a channel. Of the two, top gate TFTs are widely used.

In a conventional TFT, a polysilicon layer for source, drain and channel regions is formed on a low-temperature processible substrate and a gate is formed on the channel region.

The conventional TFT may be more highly integrated and manufactured at a lower cost because of its simple structure and manufacturing process.

However, conventional TFTs may have one or more of the following problems.

First, after the polysilicon layer is doped with dopants to form the source/drain regions, it may be difficult to completely remove a photoresist used as a mask. Accordingly, a gate contact is formed on a gate electrode where the photoresist still remains. Consequently, the gate contact may be unstable or may have a higher resistance.

Second, after the polysilicon is doped with dopants, laser beams, for example, excimer laser beams may be irradiated for activation of the dopants. In this process, the gate electrode may be damaged. Consequently, the carrier mobility in the channel may be reduced and/or the breakdown voltage of a gate insulating layer may be reduced.

### SUMMARY OF THE INVENTION

Example embodiments of the present invention provide a TFT that includes a capping layer.

Example embodiments of the present invention provide a TFT that may reduce or prevent the incomplete removal of the photoresist mask for ion doping and the damage of a gate electrode during an excimer layer beam irradiation and thus may have a more stable and/or higher-speed operation.

Example embodiments of the present invention also provide a method of manufacturing the TFT.

According to an example embodiment of the present invention, there is provided a thin film transistor including: a substrate; a buffer layer formed on the substrate; a polysilicon layer formed on the buffer layer, the polysilicon layer including a first doped region, a second doped region, and a channel region; a gate insulating layer and a gate electrode sequentially stacked on the channel region of the polysilicon layer; and a capping layer stacked on the gate electrode.

In an example embodiment, the substrate may be a transparent and flexible substrate and may be at least one selected from the group consisting of a glass substrate and a plastic substrate.

In an example embodiment, the capping layer may be at least one selected from the group consisting of a silicon oxide layer and a silicon nitride layer, and may have a thickness of 50-500 nm.

According to another example embodiment of the present invention, there is provided a method of manufacturing a thin film transistor, including: sequentially stacking a buffer layer and a polysilicon layer on a substrate; patterning the polysilicon layer; sequentially stacking a gate insulating layer and a gate electrode layer on the patterned polysilicon layer; and stacking a capping layer on the gate electrode layer.

In another example embodiment, the method further includes forming a mask on a partial region of the capping layer; and exposing the patterned polysilicon layer around the mask.

In another example embodiment, the method further includes removing the mask; doping the exposed region of the patterned polysilicon layer with conductive dopants; and activating the doped conductive dopants.

In another example embodiment, the method further includes doping the exposed region of the patterned polysilicon layer with conductive dopants; activating the doped conductive dopants; and removing the mask.

According to another example embodiment of the present invention, there is provided a method of manufacturing a thin film transistor, including: sequentially stacking a buffer layer and a polysilicon layer on a substrate; patterning the polysilicon layer; sequentially stacking a gate insulating layer and a gate electrode layer on the patterned polysilicon layer; stacking a capping layer on the gate electrode layer; forming a mask on a partial region of the capping layer; exposing the patterned polysilicon layer around the mask; removing the mask; doping the exposed region of the patterned polysilicon layer with conductive dopants; and activating the doped conductive dopants.

In an example embodiment, forming the polysilicon layer may include: forming an amorphous silicon layer on the substrate; and irradiating laser beams on the amorphous silicon layer.

In an example embodiment, the gate electrode layer may be formed of at least one selected from the group consisting of an aluminum electrode layer, a chrome electrode layer, a molybdenum electrode layer, and an AlNd electrode layer.

In an example embodiment, the capping layer may be formed of one selected from the group consisting of a silicon oxide layer and a silicon nitride (SiNₓ) layer, and may be formed to a thickness of 50-500 nm.

In an example embodiment, excimer laser beams may be irradiated onto the exposed region of the polysilicon layer for the activation of the doped conductive dopants.

In an example embodiment, the method may further include: forming an interlayer insulating layer on the buffer layer to cover the capping layer, the gate electrode layer, the gate insulating layer, and the exposed region of the patterned polysilicon layer; and forming contact holes penetrating the interlayer insulating layer to expose the doped region of the patterned polysilicon layer and another contact hole penetrating the interlayer insulating layer and the capping layer to expose the gate electrode layer.

In an example embodiment, the method may further include: removing the capping layer; forming an interlayer insulating layer on the buffer layer to cover the gate electrode layer, the gate insulating layer, and the exposed region of the patterned polysilicon layer; and forming contact holes penetrating the interlayer insulating layer to expose the doped region of the patterned polysilicon layer and another contact hole penetrating the interlayer insulating layer to expose the gate electrode layer.

According to another example embodiment of the present invention, there is provided a method of manufacturing a thin film transistor, including: sequentially stacking a buffer layer and a polysilicon layer on a substrate; patterning the polysilicon layer; sequentially stacking a gate insulating layer and a gate electrode layer on the patterned polysilicon layer; stacking a capping layer on the gate electrode layer; forming a mask on a partial region of the capping layer; exposing the patterned polysilicon layer around the mask; doping the exposed region of the patterned polysilicon layer with conductive dopants; activating the doped conductive dopants; and removing the mask.

In an example embodiment, the polysilicon layer, the gate electrode layer, and the capping layer may be formed as the same way as stated above.

In an example embodiment, excimer laser beams may be irradiated onto the exposed region of the polysilicon layer for the activation of the doped conductive dopants.

In an example embodiment, thee method may further include: forming an interlayer insulating layer on the buffer layer to cover the capping layer, the gate electrode layer, the gate insulating layer, and the exposed region of the patterned polysilicon layer; and forming contact holes penetrating the interlayer insulating layer to expose the doped region of the patterned polysilicon layer and another contact hole penetrating the interlayer insulating layer and the capping layer to expose the gate electrode layer.

In an example embodiment, the method may further include: removing the capping layer; forming an interlayer insulating layer on the buffer layer to cover the gate electrode layer, the gate insulating layer, and the exposed region of the patterned polysilicon layer; and forming contact holes penetrating the interlayer insulating layer to expose the doped region of the patterned polysilicon layer and another contact hole penetrating the interlayer insulating layer to expose the gate electrode layer.

According to example embodiments of the present invention, the remnants of the photoresist layer do not remain on the gate electrode. Also, it is possible to reduce or prevent the gate electrode from being damaged due to the excimer laser during the operation of irradiating the excimer laser beams for the activation of the dopants doped for forming the source/drain regions. Therefore, the sufficient process margin can be secured. That is, the excimer laser having sufficient intensity to activate the doped dopants may be used to irradiate the excimer laser beams on the source/drain regions. Further, because of these advantages, the carrier mobility in the channel region may be increased and/or the breakdown voltage may be increased.

### BRIEF DESCRIPTION OF THE DRAWINGS

The above and other features and advantages of the present invention will become more apparent by describing in detail example embodiments thereof with reference to the attached drawings in which:

FIG. 1 is a perspective view of a TFT according to an example embodiment of the present invention;

FIG. 2 is a sectional view taken along line I-I′ in FIG. 1;

FIGS. 3 through 19 are sectional views illustrating a method of manufacturing the TFT according to an example embodiment of the present invention;

FIGS. 20 through 22 are photographs illustrating the results of a test for comparing the characteristics of example TFTs according to the presence/absence of a capping layer;

FIG. 23 is a graph illustrating the measurement results of the stabilities of a conventional TFT and a TFT in accordance with an example embodiment of the present invention at a breakdown voltage of a gate insulating layer; and

FIG. 24 is a graph illustrating the measurement results of the carrier mobility in the conventional TFT and a TFT in accordance with an example embodiment of the present invention according to a laser annealing energy for activation of doped dopant ions.

### DETAILED DESCRIPTION OF EXAMPLE EMBODIMENTS OF THE INVENTION

The present invention will now be described more fully with reference to the accompanying drawings, in which example embodiments of the invention are shown. In the drawings, the thicknesses of layers and regions are exaggerated for clarity. Like reference numerals in the drawings denote like elements, and thus their description will be omitted.

Various example embodiments of the present invention will now be described more fully with reference to the accompanying drawings in which some example embodiments of the invention are shown. In the drawings, the thicknesses of layers and regions are exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element or layer is referred to as being “formed on” another element or layer, it can be directly or indirectly formed on the other element or layer. That is, for example, intervening elements or layers may be present. In contrast, when an element or layer is referred to as being “directly formed on” to another element, there are no intervening elements or layers present. Other words used to describe the relationship between elements or layers should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

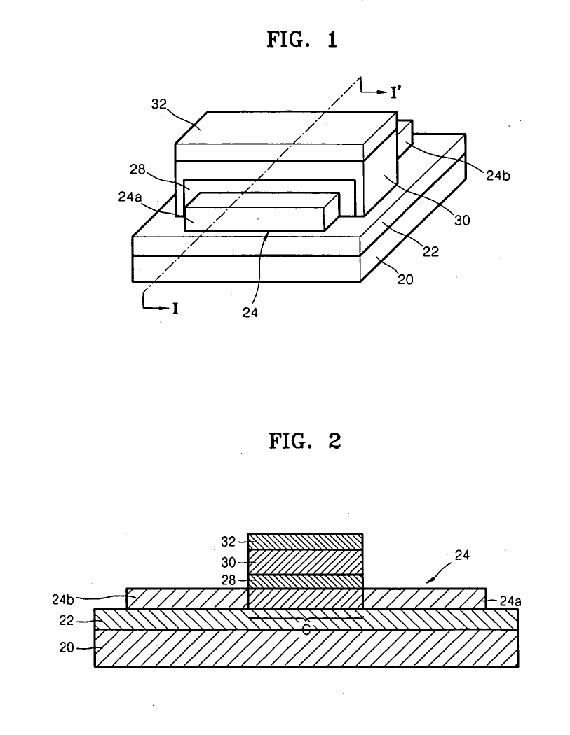

FIG. 1 is a perspective view of a TFT according to an example embodiment of the present invention, and FIG. 2 is a sectional view taken along line I-I′ in FIG. 1.

Referring to FIGS. 1 and 2, a buffer layer 22 may be disposed on a substrate 20, and a polysilicon layer 24 may be disposed on a given region of the buffer layer 22. The substrate 20 may be a transparent and flexible substrate, for example, a glass substrate or a plastic substrate, which may be used in a lower-temperature process. The buffer layer 22 reduces or prevents contact and dopant diffusion between the substrate 20 and the polysilicon layer 24. Also, the buffer layer 22 may alleviate stress between the substrate 20 and a material layer stacked on the buffer layer 22. The buffer layer 22 may be a silicon oxide layer. The silicon oxide layer may be formed using an inductively coupled plasma chemical vapor deposition (ICPCVD).

As illustrated in FIG. 2, the polysilicon layer 24 may include first and second doped regions 24a and 24b, and a channel region C disposed therebetween. The first and second doped regions 24a and 24b may be doped with conductive dopants, for example, n⁺ dopants. One of the first and second doped regions 24a and 24b is used as a source and the other is used as a drain. A gate insulating layer 28 and a gate electrode 30 may be sequentially stacked on a channel region C of the polysilicon layer 24. The gate insulating layer 28 may be a silicon oxide layer. The gate electrode 30 may be at least one selected from the group consisting of an aluminum electrode, a chrome electrode, a molybdenum electrode, and an AlNd electrode.

A capping layer 32 may be disposed on the gate electrode 30. The capping layer 32 may reduce or prevent the gate electrode 30 from being damaged during an operation of doping dopants and/or irradiating excimer laser beams after an operation of patterning the gate. The capping layer 32 may be 50-500 nm in thickness. The capping layer 32 may be a silicon oxide (SiO₂) layer or a silicon nitride (SiNₓ) layer. When an interlayer insulating layer is formed on the resulting structure illustrated in FIG. 1, a thickness difference between the interlayer insulating layer on the gate electrode 30 and the interlayer insulating layer on the first and second doped regions 24a and 24b corresponds to the thickness of the capping layer 32.

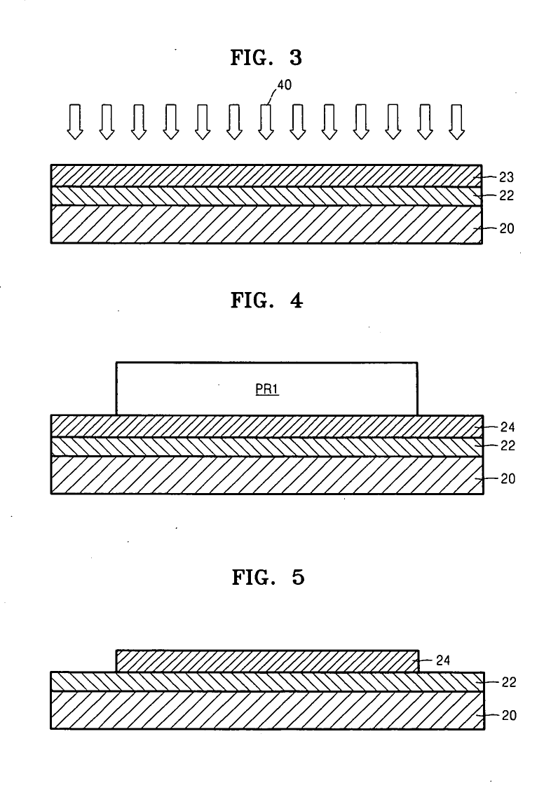

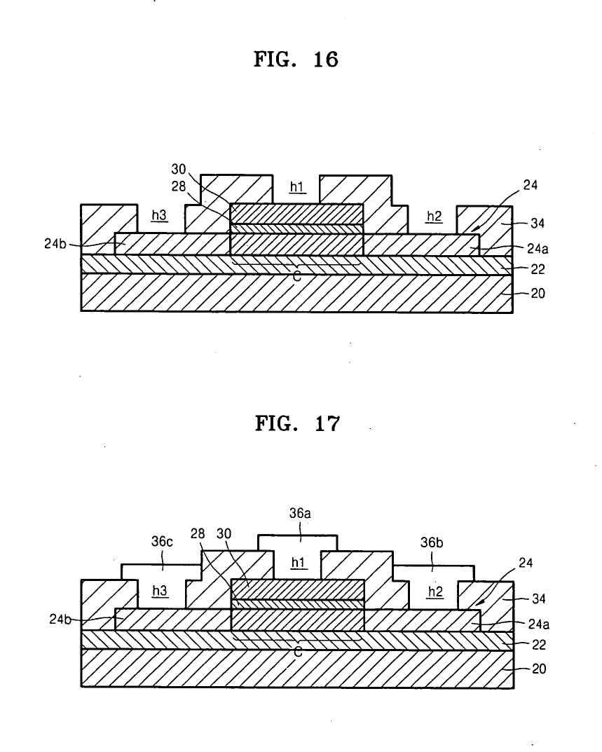

A method for manufacturing the TFT will now be described with reference to FIGS. 3 through 19.

FIGS. 3 through 19 are sectional views illustrating a method of manufacturing the TFT according to example embodiments of the present invention.

Referring to FIG. 3, a buffer layer 22 may be formed on a substrate 20. The substrate 20 may be a transparent and/or flexible substrate, for example, a glass substrate and a plastic substrate, which may be used in a lower-temperature process. The buffer layer 22 may be formed of a silicon oxide layer to a thickness of about 100 nm. The silicon oxide layer may be formed using an ICPCVD apparatus. The buffer layer 22 may also be formed of other materials suitable for forming an amorphous silicon layer. An amorphous silicon layer 23 may be formed on a surface, for example, an entire surface of the buffer layer 22. The amorphous silicon layer 23 may be formed to a thickness of about 50 nm. The buffer layer 22 and the amorphous silicon layer 23 may be formed at a lower temperature, for example, 200° C.

Excimer layer beams 40 of uniform intensity may be irradiated on the surface of the amorphous silicon layer 23. The irradiation of the excimer laser beams 40 may crystallize the amorphous silicon layer 23 at lower temperature. The irradiation of the excimer laser beams 40 may cause the amorphous silicon layer 23 to change into a crystalline polysilicon layer 24 illustrated in FIG. 4.

Referring to FIG. 4, a first photoresist pattern PR1 may be formed on a given region of the polysilicon layer 24. Using the photoresist pattern PR1 as a mask, an exposed portion of the polysilicon layer 24 is etched until the buffer layer 22 is exposed. The first photoresist pattern PR1 may be removed. As illustrated in FIG. 5, the polysilicon layer 24 may be patterned to a suitable size for forming the TFT. Because, the buffer layer 22 exists between the polysilicon layer 24 and another adjacent polysilicon layer (not shown), the polysilicon layer 24 is spaced apart and electrically isolated from the adjacent polysilicon layer.

Alternatively, the etching operation may be performed before the operation of irradiating the excimer layer beams 40.

That is, the first photoresist pattern PR1 may be formed on the amorphous silicon layer 23, the amorphous silicon layer 23 may be etched using the first photoresist pattern PR1 as a mask, and the excimer laser beams 40 may be irradiated on the amorphous silicon layer 23 to change it into the polysilicon layer 24.

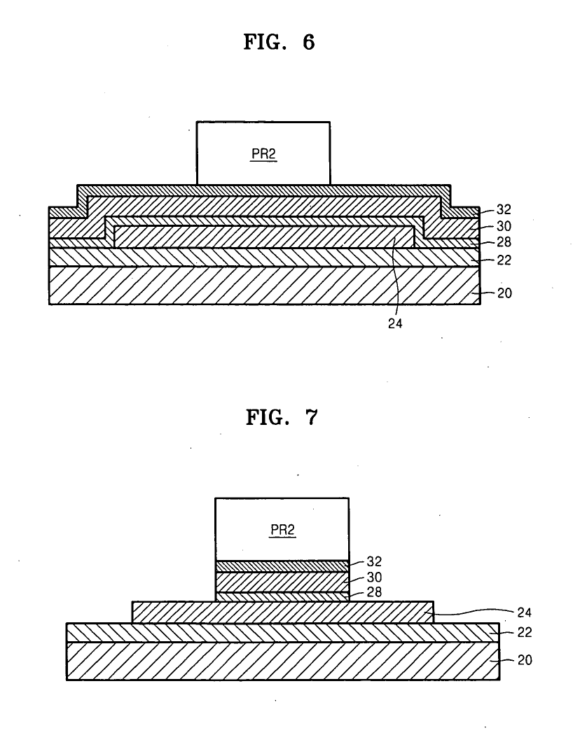

Referring to FIG. 6, a gate insulating layer 28, a material layer (hereinafter referred to as a gate electrode layer) 30 to be used as a gate electrode, and capping layer 32 are sequentially stacked on the buffer layer 22 and the polysilicon layer 24. The material layers 28, 30, and/or 32 may be formed at a lower temperature.

The gate insulating layer 28 may be formed of a silicon oxide layer. The gate electrode layer 30 may be formed of at least one selected from the group consisting of an aluminum electrode layer, a chrome electrode layer, a molybdenum electrode layer, and an AlNd electrode layer. The capping layer 32 may be formed to a thickness of about 50-500 nm.

The capping layer 32 may be formed of a silicon oxide (SiO₂) layer or a silicon nitride (SiNₓ) layer. A second photoresist pattern PR2 may be formed on the capping layer 32 so as to define a portion of polysilicon layer 24 to be used as a gate. An exposed portion of the capping layer 32 may be etched using the second photoresist pattern PR2 as a mask. Thereafter, the gate electrode 30 and the gate insulating layer 28 formed under the exposed portion of the capping layer 32 are sequentially etched under suitable conditions. The etching operation may be performed until the buffer layer 22 and the polysilicon layer 24 are exposed. Accordingly, as illustrated in FIG. 7, the gate insulating layer 28, the gate electrode 30, and the capping layer 32 remain only on a region of the polysilicon layer 24 defined by the second photosensitive pattern PR2, and the remaining portion of the polysilicon layer 24 is exposed.

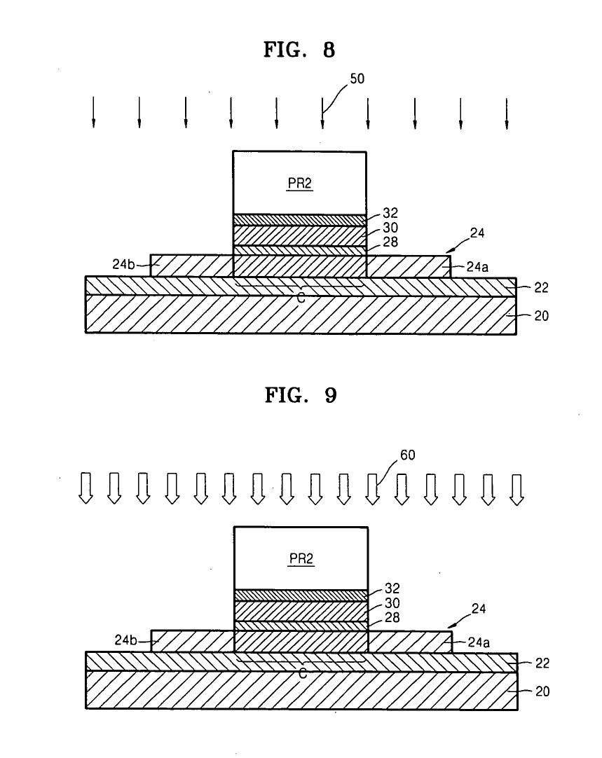

Referring to FIG. 8, using the second photoresist pattern PR2 as a mask, conductive dopant ions 50 (for example, n⁺ dopant ions) may be implanted into exposed portions 24a and 24b of the polysilicon layer 24.

Consequently, the exposed portions 24a and 24b are doped with the conductive dopant ions 50. Hereinafter, the exposed portions 24a and 24b will be referred to as a first doped region 24a and a second doped region 24b, respectively. When the first doped region 24a is a source region, the second doped region 24b is a drain region, and vice versa. The dopant ions 50 are not implanted into a portion C of the polysilicon layer 24 formed under the second photoresist pattern PR2. The portion C of the polysilicon layer 24 exists between the first and second doped regions 24a and 25b of the polysilicon layer 24. Hereinafter, the portion C will be referred to as a channel region C.

Referring to FIG. 9, in order to activate the doped dopant ions of the first and second doped regions 24a and 24b, excimer laser beams 60 are irradiated onto the exposed portions of the polysilicon layer 24 with the second photoresist pattern PR2 unremoved. For a given time the excimer laser beams 60 are irradiated at an intensity sufficient to activate the doped dopant ions of the first and second doped regions 24a and 24b. Alternatively, for a given intensity, the excimer laser beams 60 are irradiated for a time sufficient to activate the doped dopant ions of the first and second doped regions 24a and 24b. The second photoresist pattern PR2 may be removed after completion of the irradiation of the laser beams 60 to form the TFT.

In another example embodiment, the operation of implanting the conductive dopant ions 50 and the operation of irradiating the excimer laser beams 60 may be performed without the use of the second photoresist pattern PR2.

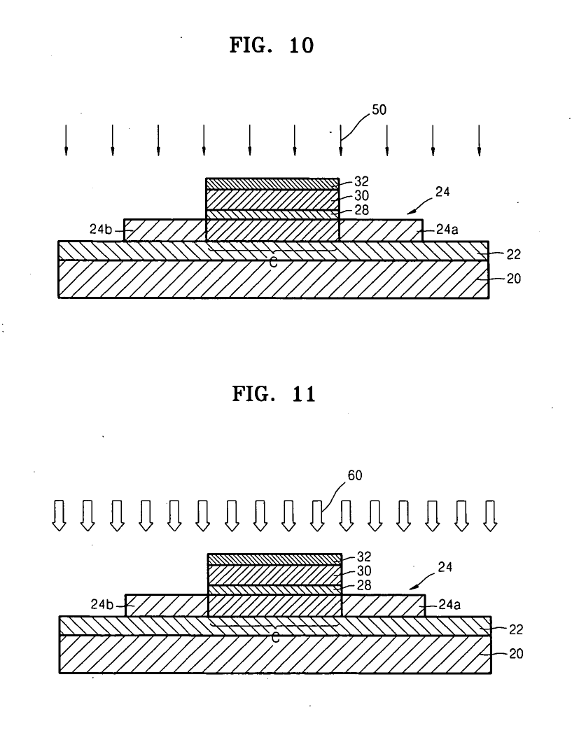

FIG. 10 illustrates implanting the conductive dopant ions 50 into the resulting structure of FIG. 7 after removing the second photoresist pattern PR2, and FIG. 11 illustrates irradiating the excimer laser beams 60 onto the resulting structure of FIG. 10.

Alternatively, after the conductive dopant ions 50 are implanted with the photoresist pattern PR2 unremoved as illustrated in FIG. 8, the excimer laser beams 60 are irradiated with the photoresist pattern PR2 removed as illustrate in FIG. 11.

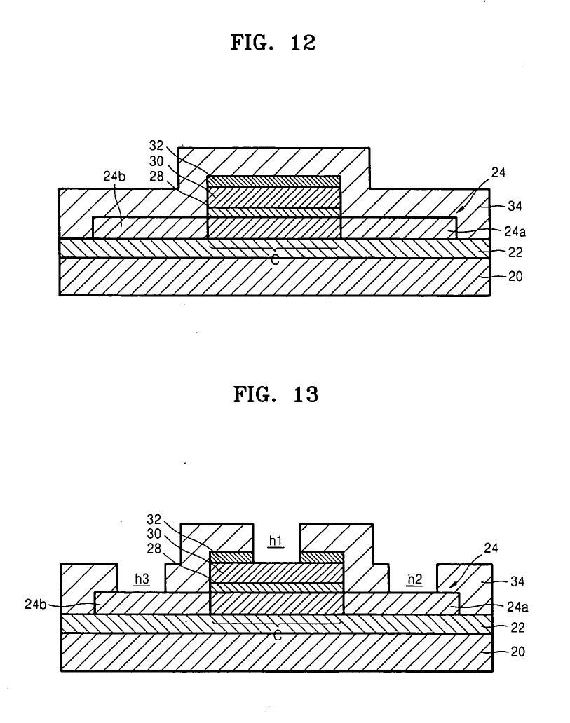

Referring to FIG. 12, after the removal of the second photoresist pattern PR2, an interlayer insulating layer 34 may be formed on the buffer layer 22 to cover the polysilicon layer 24, the gate insulating layer 28, the gate electrode layer 30, and the capping layer 32. The interlayer insulating layer 34 may be formed of a silicon oxide layer or a silicon nitride layer.

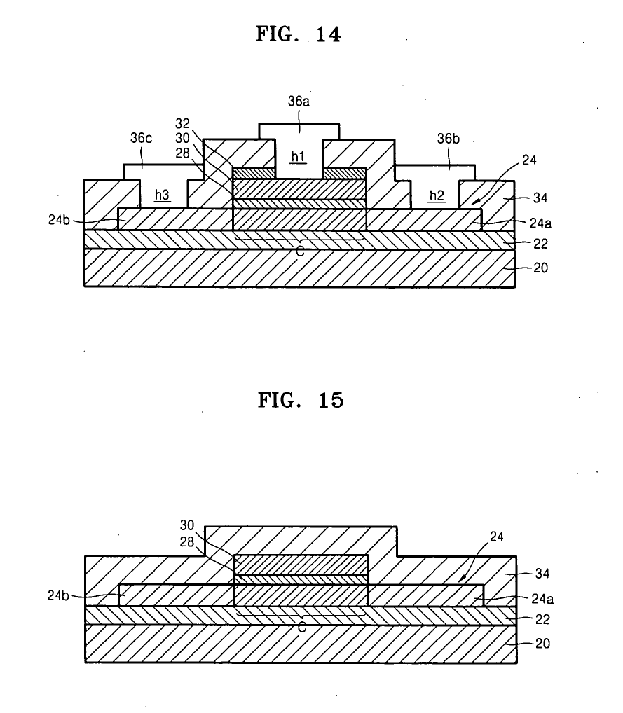

Referring to FIG. 13, first through third contact holes h1, h2 and h3 are formed on the interlayer insulating layer 34. The first contact hole h1 may penetrate the capping layer 32, and the gate electrode layer 30 may be exposed through the first contact hole h1. The first and second doped region 24a and 24b may be exposed through the second and third contact holes h2 and h3, respectively.

Referring to FIG. 14, first, second and third conductive layers 36a, 36b and 36c may be formed on the interlayer insulating layer 34 to fill the first, second and third contact holes h1, h2 and h3, respectively.

In another example embodiment of the present invention, after the excimer laser beams 60 are irradiated for activation of the doped dopant ions as illustrated in FIG. 9 and then the capping layer 32 is removed, the subsequent process described above may be performed.

For example, after the removal of the capping layer 32, the interlayer insulating layer 34 may be formed on the buffer layer 22 to cover the polysilicon layer 24, the gate insulating layer 28, and the gate electrode layer 30 and the first through third contact holes h1, h2 and h3 may be formed in the interlayer insulating layer 34, as illustrated in FIGS. 15 through 17. The first through third conductive layers 36a, 36b and 36c may be formed in the first through third contact holes h1, h2 and h3, respectively.

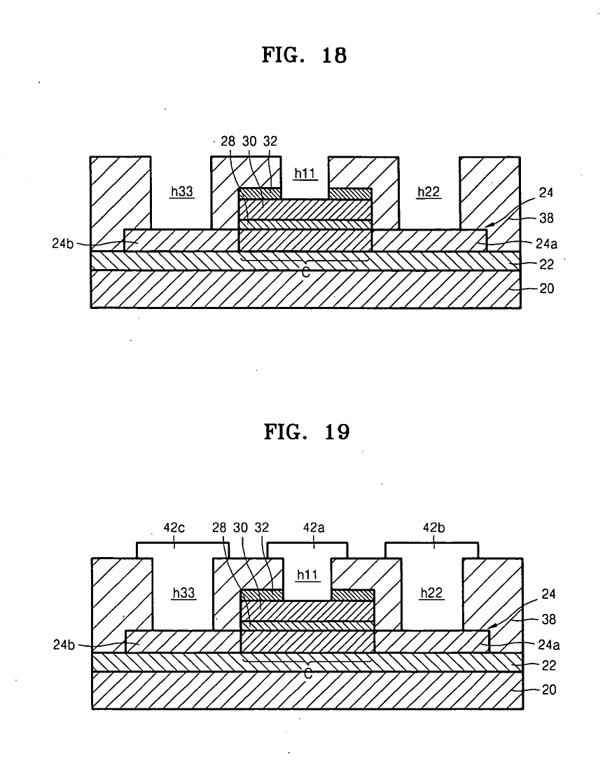

FIGS. 18 and 19 illustrate a method of manufacturing the TFT according to another example embodiment of the present invention.

For example, the excimer laser beams 60 may be irradiated as the same way as illustrated in FIG. 9, and the second photoresist pattern PR2 may be removed. An interlayer insulating layer 38 may be formed on the buffer layer 22 to cover the polysilicon layer 24, the gate insulating layer 28, the gate electrode layer 30, and the capping layer 32 as illustrate in FIG. 18. An upper surface of the interlayer insulating layer 38 may be planarized. First through third contact holes h11, h22 and h33 may be formed in the resulting interlayer insulating layer 38. The first contact hole h11 penetrates the capping layer 32, and the gate electrode layer 30 is exposed through the first contact hole h11. The first and second doped region 24a and 24b are exposed through the second and third contact holes h22 and h33, respectively.

As illustrated in FIG. 19, first, second and third conductive layers 42a, 42b and 42c may be formed on the interlayer insulating layer 38 to fill the first, second and third contact holes h11, h22 and h33, respectively

In FIG. 8, because the interlayer insulating layer 38 is formed after completion of the activation of the doped dopant ions of the first and second doped regions 24a and 24b, the capping layer 32 may be removed before the forming of the interlayer insulating layer 38.

The following tests have been performed to ascertain the characteristics of TFTs according to example embodiments of the present invention including the presence of the capping layer.

After the capping layer was formed on the gate electrode and the gate patterning was performed, the excimer laser beams were irradiated to activate the doped dopant ions of the source/drain region, with a portion of the gate electrode exposed by the removal of a portion of the capping layer. The excimer laser beams were irradiated three times at different intensities.

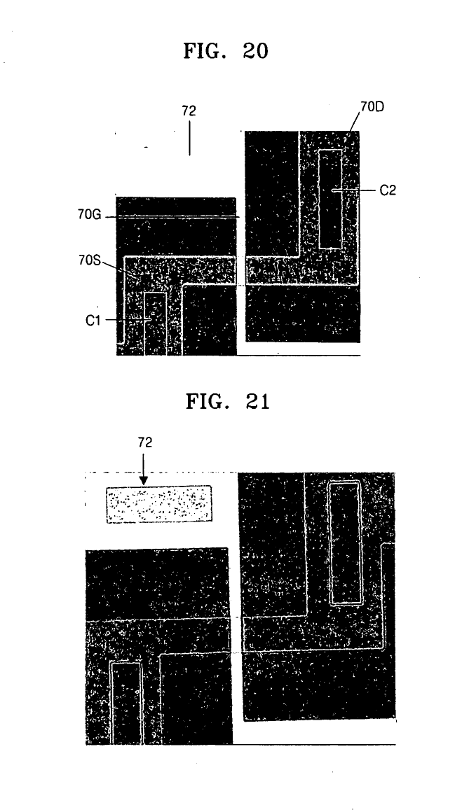

FIGS. 20 through 22 are photographs illustrating the results of the test for comparing the characteristics of TFTs according to example embodiments of the present invention including the presence of the capping layer.

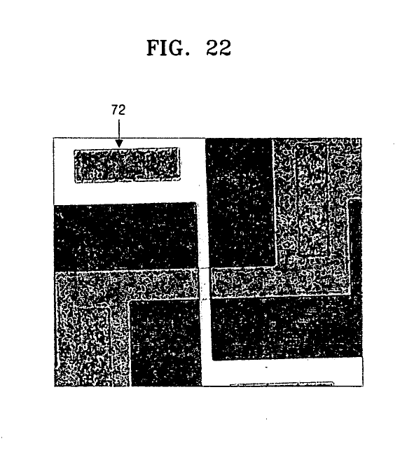

Referring to FIG. 20, reference numerals 70S, 70D and 70G denote a source, a drain and a gate, respectively. Reference numeral 72 denotes an opened region of the gate 70G, that is, a region from which the capping layer is removed. Reference numerals C1 and C2 denote a source contact and a drain contact, respectively. FIGS. 21 and 22 have the same structure as FIG. 20, and thus only the reference numeral 72 denoting the opened region of the gate 70G is illustrated in FIGS. 21 and 22, for simplicity.

FIG. 20 illustrates the test result obtained when the excimer laser beams with an energy density of 450 mJ/cm² are irradiated once in a pulse mode, FIG. 21 illustrates the test result obtained when the excimer laser beams with an energy density of 550 mJ/cm² are irradiated once in a pulse mode, and FIG. 22 illustrates the test result obtained when the excimer laser beams with an energy density of 650 mJ/cm² are irradiated once in a pulse mode.

As can be seen from FIGS. 20 through 22, when the energy density is 550 mJ/cm², the region 72 and a region of the gate electrode 70G from which the capping layer is removed are not changed. On the contrary, when the energy density is 650 mJ/cm², the region 72 is darker than that of when the energy density is 450 mJ/cm² or 550 mJ/cm². However, the remaining region of the gate electrode 70G is not changed. This result shows that when the excimer laser beams are irradiated with the capping layer formed on the gate electrode, the gate electrode is not damaged even when the energy density is sufficient to damage a portion of the gate electrode on which the capping layer is not formed.

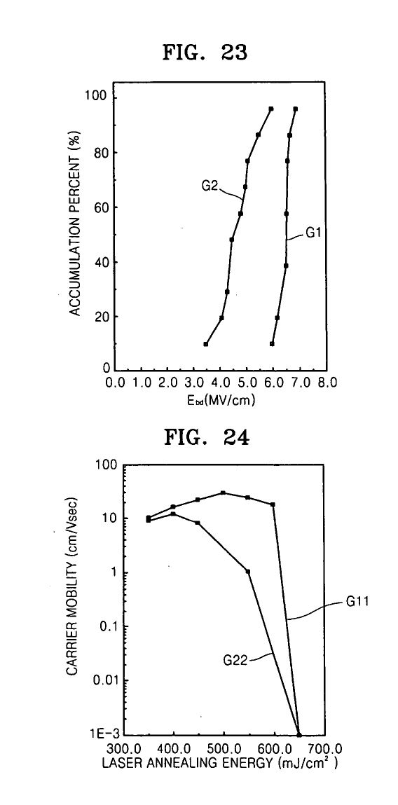

FIG. 23 is a graph illustrating the measurement results of the stabilities of a conventional TFT and a TFT in accordance with an example embodiment of the present invention having a capping layer at a breakdown voltage of a gate insulating layer.

In FIG. 23, a first graph G1 shows the test result for the TFT according to an example embodiment of the present invention, and a second graph G2 shows the test result for the conventional TFT. The horizontal axis represents an insulation breakdown voltage Ebd, and the vertical axis represents a ratio of TFTs in which a insulating property of the gate insulating layer is broken down at a given insulation breakdown voltage Ebd. For example, when the insulation breakdown voltage Ebd is 4 [MV/cm], that the vertical axis is 20% means that the insulation property of the gate insulating layer in 20% of the whole TFTs is broken down at the insulation breakdown voltage of 4 [MV/cm].

As can be seen from the second graph G2, when the insulation breakdown voltage slightly exceeds 3 [MV/cm], the gate insulating layer breaks down in some TFTs. At the starting point of the first graph G1, the value at the vertical axis of the second graph G2 has already reached 100. This means that the insulation property of the gate insulating layer in all the TFTs breaks down at the insulation breakdown voltage Ebd of 6 [MV/cm]. However, in case of the first graph G1, the insulation property of the gate insulating layer in any TFT is not broken down until the insulation breakdown voltage Ebd reaches 6 [MV/cm].

From this comparison results, it can be seen that a TFT according to an example embodiment of the present invention has higher stability and/or insulation breakdown voltage than those of the conventional TFT.

An effect of a TFT according to example embodiment of the present invention may be found in the carrier mobility.

FIG. 24 is a graph illustrating the measurement results of the carrier mobility in a conventional TFT and a TFT in accordance with an example embodiment of the present invention according to a laser annealing energy for activation of doped dopant ions.

In FIG. 24, a first graph G11 represents the measurement result of the TFT according to an example embodiment of the present invention, and a second graph G22 represents the measurement of a conventional TFT.

As can be seen from the graph G22, the carrier mobility is reduced to below 10 cm/Vsec when the laser annealing energy exceeds 400 mJ/cm². However, as can be seen from the graph G11, the carrier mobility is not reduced even when the laser annealing energy exceeds 600 mJ/cm².

Through these results, the carrier mobility of the TFT according to example embodiments of the present invention is less influenced by laser annealing energy compared with a conventional TFT.

As described above, because the TFT according to example embodiments of the present invention includes the capping layer on the gate electrode, it is possible to reduce or prevent the gate electrode from being damaged during the operation of doping the dopants and the operation of irradiating the excimer laser beam for activation of the dopants. Accordingly, the insulation breakdown voltage may be increased and/or the influence of the excimer laser beam irradiation on the carrier mobility may be reduced or minimized. Consequently, the stability and/or high-speed operation of the TFT may be obtained. Also, the presence of the capping layer allows a wider process margin in the manufacturing process. Further, because the doping operation and/or the laser beam irradiation operation may be performed after the photoresist layer is removed, the problems associated with the removal of the photoresist layer may be solved.

While the present invention has been particularly shown and described with reference to example embodiments thereof, it will be understood by those of ordinary skill in the art that various changes in form and details may be made therein without departing from the spirit and scope of the present invention as defined by the following claims.

What is claimed is:

1. A thin film transistor (TFT) comprising:
a substrate;
a buffer layer formed on the substrate;
a polysilicon layer formed on the buffer layer, the polysilicon layer including a first doped region, a second doped region, and a channel region;
a gate insulating layer and a gate electrode sequentially stacked on the channel region of the polysilicon layer; and
a capping layer stacked on the gate electrode.

2. The thin film transistor of claim 1, wherein the substrate is at least one selected from the group consisting of a glass substrate and a plastic substrate.

3. The thin film transistor of claim 1, wherein the capping layer has a thickness of 50-500 nm.

4. The thin film transistor of claim 1, wherein the capping layer is at least one selected from the group consisting of a silicon oxide layer and a silicon nitride layer.

5. The thin film transistor of claim 1, wherein the gate electrode is formed of at least one selected from the group consisting of Al, Cr, Mo, and AlNd.

6. The thin film transistor of claim 1, wherein the buffer layer is a silicon oxide layer.

7. A method of manufacturing a thin film transistor, comprising:
sequentially stacking a buffer layer and a polysilicon layer on a substrate;
patterning the polysilicon layer;
sequentially stacking a gate insulating layer and a gate electrode layer on the patterned polysilicon layer; and
stacking a capping layer on the gate electrode layer.

8. The method of claim 7, further comprising:
forming a mask on a partial region of the capping layer; and
exposing the patterned polysilicon layer around the mask.

9. The method of claim 8, further comprising:
removing the mask;
doping the exposed region of the patterned polysilicon layer with conductive dopants; and
activating the doped conductive dopants.

10. The method of claim 9, wherein forming the polysilicon layer comprises:
forming an amorphous silicon layer on the substrate; and
irradiating laser beams on the amorphous silicon layer.

11. The method of claim 9, wherein the gate electrode layer is formed of one selected from the group consisting of an aluminum electrode layer, a chrome electrode layer, a molybdenum electrode layer, and an AlNd electrode layer.

12. The method of claim 9, wherein the capping layer is formed to a thickness of 50-500 nm.

13. The method of claim 9, wherein the capping layer is formed of one selected from the group consisting of a silicon oxide layer and a silicon nitride (SiNₓ) layer.

14. The method of claim 9, wherein activating the doped conductive dopants comprises irradiating excimer laser beams onto the exposed region of the polysilicon layer to activate the doped conductive dopants.

15. The method of claim 9, further comprising:
forming an interlayer insulating layer on the buffer layer to cover the capping layer, the gate electrode layer, the gate insulating layer, and the exposed region of the patterned polysilicon layer; and
forming contact holes penetrating the interlayer insulating layer to expose the doped region of the patterned polysilicon layer and another contact hole penetrating the interlayer insulating layer and the capping layer to expose the gate electrode layer.

16. The method of claim 9, further comprising:
removing the capping layer;
forming an interlayer insulating layer on the buffer layer to cover the gate electrode layer, the gate insulating layer, and the exposed region of the patterned polysilicon layer; and
forming contact holes penetrating the interlayer insulating layer to expose the doped region of the patterned polysilicon layer and another contact hole penetrating the interlayer insulating layer to expose the gate electrode layer.

17. The method of claim 8, further comprising:
doping the exposed region of the patterned polysilicon layer with conductive dopants;
activating the doped conductive dopants; and
removing the mask.

18. The method of claim 17, wherein the forming of the polysilicon layer comprises:
forming an amorphous silicon layer on the substrate; and
irradiating laser beams on the amorphous silicon layer.

19. The method of claim 17, wherein the gate electrode layer is formed of one selected from the group consisting of an aluminum electrode layer, a chrome electrode layer, a molybdenum electrode layer, and an AlNd electrode layer.

20. The method of claim 17, wherein the capping layer is formed to a thickness of 50-500 nm.

21. The method of claim 17, wherein the capping layer is formed of one selected from the group consisting of a silicon oxide layer and a silicon nitride (SiNₓ) layer.

22. The method of claim 17, wherein the activating the doped conductive dopants comprises irradiating excimer laser beams onto the exposed region of the polysilicon layer to activate the doped conductive dopants.

23. The method of claim 17, further comprising:
forming an interlayer insulating layer on the buffer layer to cover the capping layer, the gate electrode layer, the gate insulating layer, and the exposed region of the patterned polysilicon layer; and
forming contact holes penetrating the interlayer insulating layer to expose the doped region of the patterned polysilicon layer and another contact hole penetrating the interlayer insulating layer and the capping layer to expose the gate electrode layer.

24. The method of claim 17, wherein the removing the capping layer comprises:
forming an interlayer insulating layer on the buffer layer to cover the gate electrode layer, the gate insulating layer, and the exposed region of the patterned polysilicon layer; and
forming contact holes penetrating the interlayer insulating layer to expose the doped region of the patterned polysilicon layer and another contact hole penetrating the interlayer insulating layer to expose the gate electrode layer.
